(19) United States
(12) Patent Application Publication
(10) Pub. No.: US 2020/0335700 A1
(43) Pub. Date: Oct. 22, 2020

(54) METHOD OF MANUFACTURING ORGANIC SEMICONDUCTOR DEVICES

(71) Applicant: Flexenable Limited, Cambridge (GB)

(72) Inventors: Patrick Too, Cambridge (GB); Herve Vandekerckhove, Cambridge (GB)

(21) Appl. No.: 16/764,511

(22) PCT Filed: Nov. 12, 2018
(86) PCT No.: PCT/EP2018/080913

§ 371 Date: May 15, 2020

(30) Foreign Application Priority Data
Nov. 17, 2017 (GB) 1719082.8

(51) Int. Cl. H01L 51/00; H01L 51/05

(52) U.S. Cl. CPC H01L 51/0023; H01L 51/055

(57) ABSTRACT

A technique comprising: forming a patterned mask over an organic semiconductor layer; using the patterned mask to pattern a layer over the organic semiconductor layer; exposing the patterned mask to radiation that renders the patterned mask soluble in a solvent; and then dissolving away the patterned mask using the solvent.

Organic semiconductor devices typically comprise a stack of layers including at least one organic semiconductor layer. Patterning of the layers typically uses a patterned photoresist mask which is removed before deposition of the next layer. A stripping agent is used in a single step process to remove the patterned photoresist mask by chemical reaction.

The inventors for the present invention have found that a stripping agent can negatively affect the performance of the organic semiconductor device when used to remove a patterned photoresist mask used to pattern a layer above an organic semiconductor layer in a stack of layers.

There is hereby provided a method comprising: forming a patterned mask over an organic semiconductor layer; using the patterned mask to pattern a layer over the organic semiconductor layer; exposing the patterned mask to radiation that renders the patterned mask soluble in a solvent; and then dissolving away the patterned mask using the solvent.

According to one embodiment, the patterned mask is removable by chemical reaction with an organic amine compound.

According to one embodiment, said organic amine compound is an amino alcohol.

According to one embodiment, said amino alcohol is amino ethanol.

According to one embodiment, said patterned mask comprises a cross-linked cresol-formaldehyde type polymer.

According to one embodiment, the method comprises using the patterned mask to pattern a conductor layer to produce a conductor pattern defining an array of gate conductors for an array of top-gate transistors.

According to one embodiment, the method comprises using the patterned mask to pattern a conductor layer to produce a conductor pattern defining an array of conductors, each in contact with a respective conductor element of a lower conductor pattern below the organic semiconductor layer.

An embodiment of the invention is described in detail hereunder, by way of example only, in which:

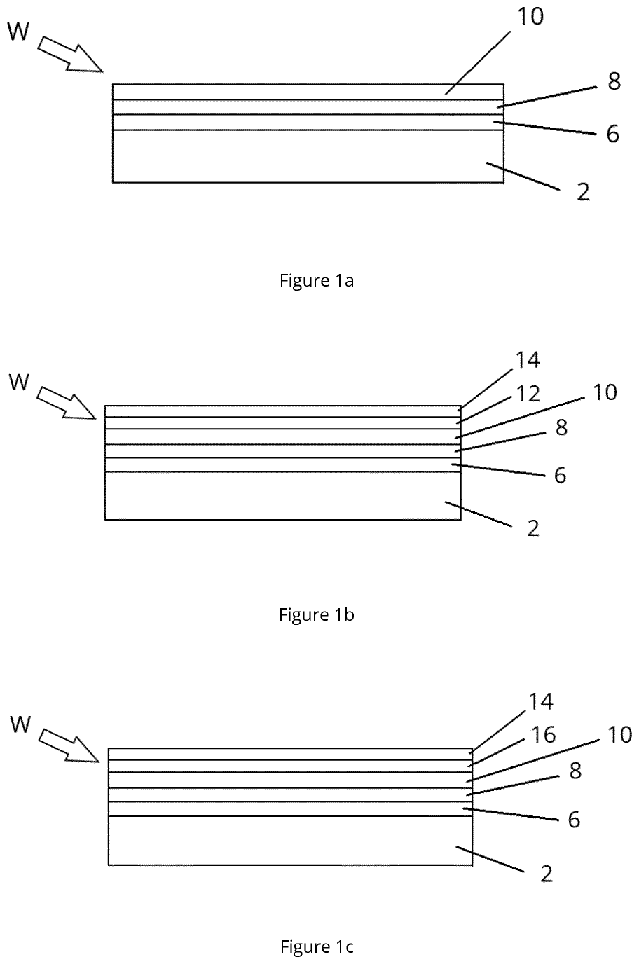

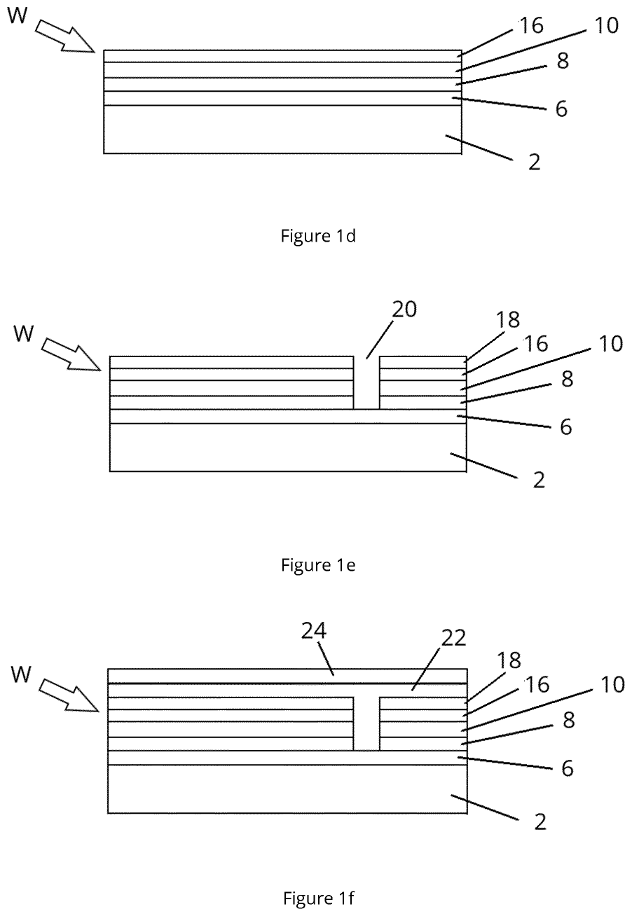

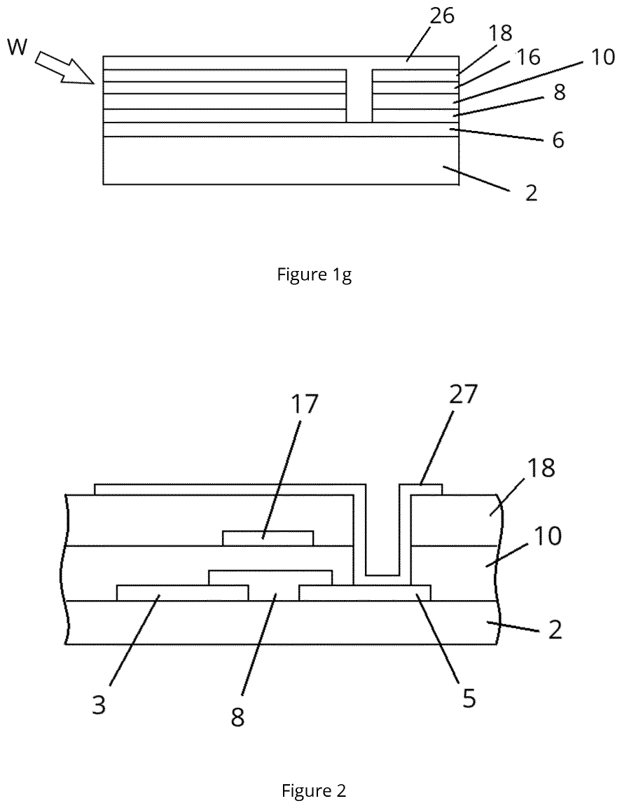

FIGS. 1(a) to 1(g) illustrates an example of a technique according to an embodiment of the present invention; and

FIG. 2 illustrates one example of a device architecture for the technique of FIGS. 1(a) to 1(g).

An embodiment is described below for the example of the production of an array of top-gate transistors, but the same technique is equally applicable to the production of other types or arrays of transistors, or the production of other types of devices including a stack of layers comprising one or more organic semiconductor layers.

Also, the embodiment described below is for the example of forming a gate conductor pattern and/or a pixel conductor pattern in the production of an array of top-gate transistors, but the same technique is equally applicable to the formation of other conductor patterns at any level above the organic semiconductor.

In one example embodiment, the technique is used for the production of an organic liquid crystal display (OLCD) device, which comprises an organic transistor device (such as an organic thin film transistor (OTFT) device) for the control component. OTFTs comprise an organic semiconductor (such as e.g. an organic polymer or small-molecule semiconductor) for the semiconductor channels.

FIGS. 1(a) to 1(g) show the processing of a workpiece W from the stage where it comprises a support film 2 such as a plastic support film, supporting a stack of layers including a source-drain conductor pattern 6 defining source and drain conductors for an array of transistors, a patterned or unpatterned layer of organic semiconductor material (such as an organic polymer semiconductor) 8 providing the semiconductor channels for the array of transistors, and one or more electrically insulating, dielectric layers 10 providing the gate dielectric for the array of transistors.

A continuous layer 12 of conductor material or a stack 12 of continuous layers including at least one layer of conductor material are deposited on the workpiece W over the gate dielectric 10. For example, a layer of metal or metal alloy or a stack of metal/metal alloy layers may be deposited on the workpiece W by e.g. a vapour deposition process such as sputtering.

A patterned mask 14 is then formed on the workpiece W over the one or more conductor layers 12. The patterned mask 14 may be formed e.g. by a photolithographic technique.

The conductor layer or stack 12 is then etched through the patterned mask 14 to produce a gate conductor pattern 16 defining an array of gate conductors 17 providing the gate electrodes for the array of transistors.

The workpiece W is then subjected to a flood UV exposure to render the whole of the patterned mask 14 soluble in a solvent, and immersed in a bath of the solvent to dissolve away the patterned mask 14.

A continuous layer 18 of electrically insulating material or a stack 18 of continuous layers of insulating material is then formed on the workpiece W over the gate conductor pattern 16, and patterned to define vias 20 extending down to each drain conductor of the source-drain conductor pattern 6. The term source conductor is used here to refer to conductors extending to the edge of the transistor array for connection to a terminals of a chip such as a driver chip, and the term drain conductor is used here to refer to a conductor that is connected to the terminals of the chip via the semiconductor channels of the transistors.

A continuous layer 22 of conductor material or a stack 22 of continuous layers including at least one conductor layer are then formed on the workpiece W over the insulating layer/stack 22. For example, a layer of metal or metal alloy or a stack of metal/metal alloy layers may be deposited on the workpiece W by e.g. a vapour deposition process such as sputtering.

A patterned mask 24 is then formed on the workpiece W over the conductor layer/stack. The patterned mask 24 may be formed e.g. by a photolithographic technique.

The conductor layer/stack 22 is then etched through the patterned mask 24 to produce a pixel conductor pattern 26 defining an array of pixel conductors 27 each contacting a respective drain conductor of the source/drain conductor pattern 6 via the via-holes 20.

The workpiece W is then subjected to a flood UV exposure to render the whole of the patterned mask 24 soluble in a solvent, and immersed in a bath of the solvent to dissolve away the patterned mask 24.

It has been found that the transistor array exhibits better performance with this technique compared to both (a) a control experiment in which both the patterned masks were removed by chemical reaction using a stripping agent comprising aminoethanol, and (b) a control experiment in which the patterned mask for producing the gate conductor pattern was removed according to the technique described above, but the patterned mask for producing the pixel conductor pattern was removed by chemical reaction using a stripping agent comprising aminoethanol.

In addition to any modifications explicitly mentioned above, it will be evident to a person skilled in the art that various other modifications of the described embodiment may be made within the scope of the invention.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features.

1. A method comprising: forming a patterned mask over an organic semiconductor layer; using the patterned mask to pattern a layer over the organic semiconductor layer; exposing the patterned mask to radiation that renders the patterned mask soluble in a solvent; and then dissolving away the patterned mask using the solvent.

2. The method according to claim 1, wherein the patterned mask is removable by chemical reaction with an organic amine compound.

3. The method according to claim 2, wherein the organic amine compound is an amino alcohol.

4. The method according to claim 3, wherein the amino alcohol is amino ethanol.

5. The method according to claim 1, wherein the patterned mask comprises a cross-linked cresol-formaldehyde type polymer.

6. The method according to claim 1, comprising using the patterned mask to pattern a conductor layer to produce a conductor pattern defining an array of gate conductors for an array of top-gate transistors.

7. The method according to claim 1, comprising using the patterned mask to pattern a conductor layer to produce a conductor pattern defining an array of conductors, each in contact with a respective conductor element of a lower conductor pattern below the organic semiconductor layer.
